(19) United States
(12) Patent Application Publication
(10) Pub. No.: US 2018/0091108 A1
(43) Pub. Date: Mar. 29, 2018

(54) OPTIMIZATION FOR ENERGY EFFICIENT MULTI-CHANNEL COMMUNICATION WITH SHARED LNA STRUCTURE

(71) Applicant: QUALCOMM Incorporated, San Diego, CA (US)

(72) Inventors: Pengkai ZHAO, San Jose, CA (US); Supratik BHATTACHARJEE, San Diego, CA (US); Jong Hyeon PARK, San Jose, CA (US); Parvathanathan SUBRAHMANYA, Sunnyvale, CA (US); Brian Clarke BANISTER, San Diego, CA (US); Madihally NARASIMHA, Saratoga, CA (US)

(21) Appl. No.: 15/712,884

(22) Filed: Sep. 22, 2017

Related U.S. Application Data
(60) Provisional application No. 62/401,084, filed on Sep. 28, 2016.

(51) Int. Cl. H03G 3/30; H04B 7/06; H04W 72/06; H04W 28/04

(52) U.S. Cl. CPC H03G 3/3078; H04B 7/0617; H04W 24/02; H04W 28/048; H04W 72/06

(57) ABSTRACT

A method, a computer-readable medium, and an apparatus are disclosed for energy efficient multichannel communications. In one aspect, the apparatus may communicate using a plurality of channels working in parallel where the plurality of channels may share an LNA. Additionally, the apparatus may determine a set of parameters for the plurality of channels to maximize energy efficiency. The apparatus may therefore configure the plurality of channels based on the set of parameters. As such, the apparatus supports multichannel communications with a common LNA structure while providing energy optimization for the multichannel communications. Accordingly, multichannel communications can be provided using a shared LNA structure that reduces implementation cost and more efficiently utilizes available power resources.

### CROSS-REFERENCE TO RELATED APPLICATION

This application claims the benefit of U.S. Provisional Application Ser. No. 62/401,084, entitled “OPTIMIZATION FOR ENERGY EFFICIENT MULTI-CHANNEL COMMUNICATION WITH SHARED LNA” and filed on Sep. 28, 2016, which is expressly incorporated by reference herein in its entirety.

### BACKGROUND

### Field

The present disclosure relates generally to communication systems, and more particularly, to a multi-channel communication system.

### Background

Wireless communication systems are widely deployed to provide various telecommunication services such as telephony, video, data, messaging, and broadcasts. Typical wireless communication systems may employ multiple-access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is Long Term Evolution (LTE). LTE is a set of enhancements to the Universal Mobile Telecommunications System (UMTS) mobile standard promulgated by Third Generation Partnership Project (3GPP). LTE is designed to support mobile broadband access through improved spectral efficiency, lowered costs, and improved services using OFDMA on the downlink, SC-FDMA on the uplink, and multiple-input multiple-output (MIMO) antenna technology. However, as the demand for mobile broadband access continues to increase, there exists a need for further improvements in LTE technology. These improvements may also be applicable to other multi-access technologies and the telecommunication standards that employ these technologies.

Multichannel communication is a promising scheme in modern high-speed wireless systems where devices in a wireless network communicate over multiple parallel channels simultaneously. Multichannel communication may bring in higher throughput but may introduce design and implementation challenges in hardware and radio frequency (RF) complexity.

For instance, circuitry may be provided for each channel and thus implementation cost of a multichannel communication system may increase linearly with the number of aggregated channels. Furthermore, multichannel communication systems may result in lower energy efficiency due to the need to power independent circuitry for each channel. Additionally, multichannel communication systems do not take into account channel fading for each channel, thereby resulting in power settings with significant power inefficiencies.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In this disclosure, systems and techniques are disclosed for multichannel downlink (DL) communication that optimize transmit power in a base station and a (low noise amplifier) LNA gain of a shared LNA structure in user equipment (UE). In one aspect, a method, a computer-readable medium, and an apparatus for wireless communication are disclosed. The apparatus may communicate using a plurality of channels working in parallel. The plurality of channels may share an LNA. To optimize power resources, the apparatus may determine a set of parameters for the plurality of channels to maximize energy efficiency. The apparatus may then configure the plurality of channels based on the set of parameters. In some implementations, the set of parameters may be constrained by any of a maximum transmit power per channel, a maximum analog-to-digital converter (ADC) input power, a maximum baseband signal-to-noise ratio (SNR), and a maximum LNA gain. Additionally, the energy efficiency may be measured by the number of transmitted bits per unit energy. The apparatus optimizing the power resources may be a base station and/or a UE.

Since the channels share the LNA, the implementation cost may be reduced as separate LNAs may not be needed for each of the channels thereby significantly reducing system and RF complexity. Furthermore, the power utilized for amplification may be reduced because separate LNAs do not have to be powered to provide amplification in the UE. Finally, by determining the set of parameters for the plurality of channels to maximize energy efficiency, the optimal transmit power and the optimal LNA gain can be provided during multichannel DL communications. The set of parameters may take into account the channel fading of each of the channels and thereby optimize the energy efficiency of the system despite variations in channel conditions.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

FIG. 1 is a diagram illustrating an example of a wireless communications system and an access network.

FIGS. 2A, 2B, 2C, and 2D are diagrams illustrating LTE examples of a DL frame structure, DL channels within the DL frame structure, an UL frame structure, and UL channels within the UL frame structure, respectively.

FIG. 3 is a diagram illustrating an example of an evolved Node B (eNB) and a UE in an access network.

FIG. 4 illustrate an example receive circuit that may be provided in the UE shown in FIG. 3.

FIGS. 5A, 5B, and 5C illustrate a flowchart of a method of wireless communication.

FIG. 6 is a conceptual data flow diagram illustrating the data flow between different means/components in an example apparatus.

FIG. 7 is a diagram illustrating an example of a hardware implementation for an apparatus employing a processing system.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of telecommunication systems will now be presented with reference to various apparatus and methods. These apparatus and methods will be described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

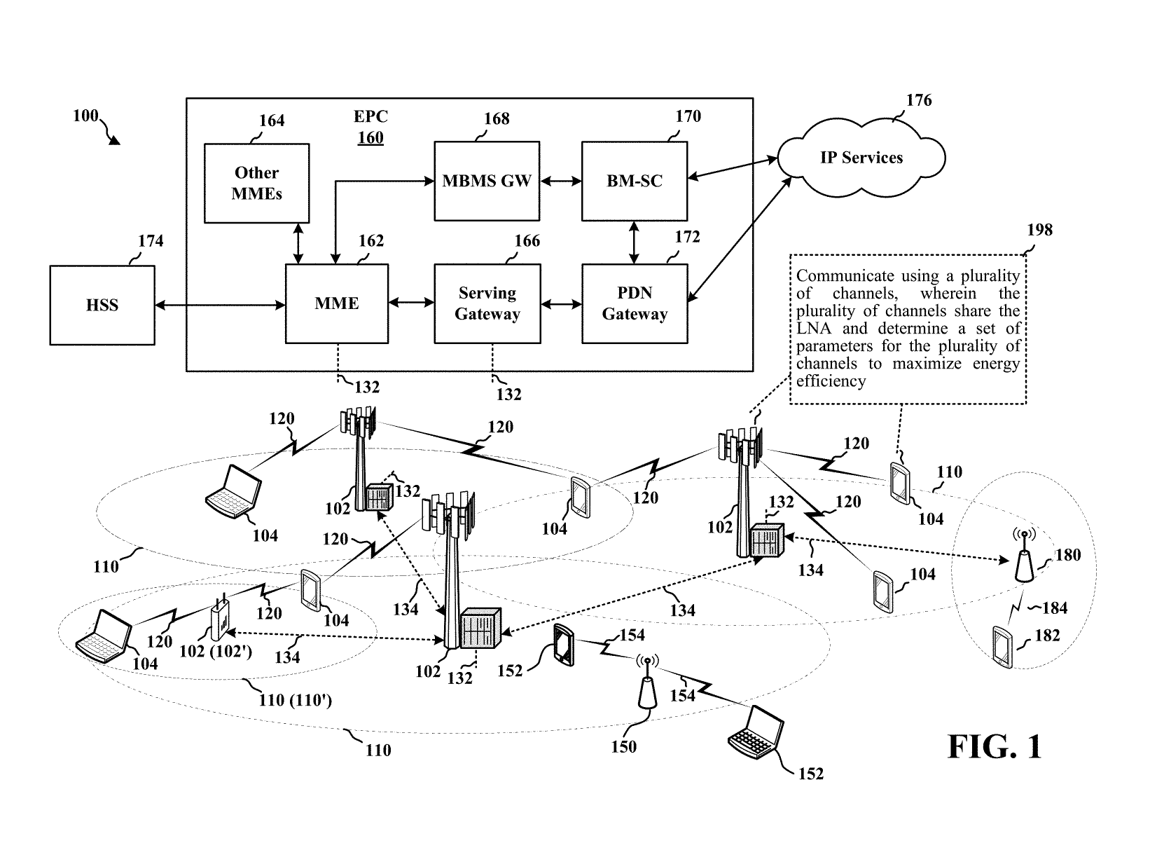

FIG. 1 is a diagram illustrating an example of a wireless communications system and an access network 100. The wireless communications system (also referred to as a wireless wide area network (WWAN)) includes base stations 102, UEs 104, and an Evolved Packet Core (EPC) 160. The base stations 102 may include macro cells (high power cellular base station) and/or small cells (low power cellular base station). The macro cells include eNBs. The small cells include femtocells, picocells, and microcells.

The base stations 102 (collectively referred to as Evolved Universal Mobile Telecommunications System (UMTS) Terrestrial Radio Access Network (E-UTRAN)) interface with the EPC 160 through backhaul links 132 (e.g., S1 interface). In addition to other functions, the base stations 102 may perform one or more of the following functions: transfer of user data, radio channel ciphering and deciphering, integrity protection, header compression, mobility control functions (e.g., handover, dual connectivity), inter-cell interference coordination, connection setup and release, load balancing, distribution for non-access stratum (NAS) messages, NAS node selection, synchronization, radio access network (RAN) sharing, multimedia broadcast multicast service (MBMS), subscriber and equipment trace, RAN information management (RIM), paging, positioning, and delivery of warning messages. The base stations 102 may communicate directly or indirectly (e.g., through the EPC 160) with each other over backhaul links 134 (e.g., X2 interface). The backhaul links 134 may be wired or wireless.

The base stations 102 may wirelessly communicate with the UEs 104. Each of the base stations 102 may provide communication coverage for a respective geographic coverage area 110. There may be overlapping geographic coverage areas 110. For example, the small cell 102′ may have a coverage area 110′ that overlaps the coverage area 110 of one or more macro base stations 102. A network that includes both small cell and macro cells may be known as a heterogeneous network. A heterogeneous network may also include Home Evolved Node Bs (eNBs) (HeNBs), which may provide service to a restricted group known as a closed subscriber group (CSG). The communication links 120 between the base stations 102 and the UEs 104 may include uplink (UL) (also referred to as reverse link) transmissions from a UE 104 to a base station 102 and/or DL (also referred to as forward link) transmissions from a base station 102 to a UE 104. The communication links 120 may use MIMO antenna technology, including spatial multiplexing, beamforming, and/or transmit diversity. The communication links may be through one or more carriers. The base stations 102/UEs 104 may use spectrum up to Y MHz (e.g., 5, 10, 15, 20 MHz) bandwidth per carrier allocated in a carrier aggregation of up to a total of Yx MHz (x component carriers) used for transmission in each direction. The carriers may or may not be adjacent to each other. Allocation of carriers may be asymmetric with respect to DL and UL (e.g., more or less carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

The wireless communications system may further include a Wi-Fi access point (AP) 150 in communication with Wi-Fi stations (STAs) 152 via communication links 154 in a 5 GHz unlicensed frequency spectrum. When communicating in an unlicensed frequency spectrum, the STAs 152/AP 150 may perform a clear channel assessment (CCA) prior to communicating in order to determine whether the channel is available.

The small cell 102′ may operate in a licensed and/or an unlicensed frequency spectrum. When operating in an unlicensed frequency spectrum, the small cell 102′ may employ LTE and use the same 5 GHz unlicensed frequency spectrum as used by the Wi-Fi AP 150. The small cell 102′, employing LTE in an unlicensed frequency spectrum, may boost coverage to and/or increase capacity of the access network. LTE in an unlicensed spectrum may be referred to as LTE-unlicensed (LTE-U), licensed assisted access (LAA), or MuLTEfire.

The millimeter wave (mmW) base station 180 may operate in mmW frequencies and/or near mmW frequencies in communication with the UE 182. Extremely high frequency (EHF) is part of the RF in the electromagnetic spectrum. EHF has a range of 30 GHz to 300 GHz and a wavelength between 1 millimeter and 10 millimeters. Radio waves in the band may be referred to as a millimeter wave. Near mmW may extend down to a frequency of 3 GHz with a wavelength of 100 millimeters. The super high frequency (SHF) band extends between 3 GHz and 30 GHz, also referred to as centimeter wave. Communications using the mmW/near mmW radio frequency band has extremely high path loss and a short range. The mmW base station 180 may utilize beamforming 184 with the UE 182 to compensate for the extremely high path loss and short range.

The EPC 160 may include a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and a Packet Data Network (PDN) Gateway 172. The MME 162 may be in communication with a Home Subscriber Server (HSS) 174. The MME 162 is the control node that processes the signaling between the UEs 104 and the EPC 160. Generally, the MME 162 provides bearer and connection management. All user Internet protocol (IP) packets are transferred through the Serving Gateway 166, which itself is connected to the PDN Gateway 172. The PDN Gateway 172 provides UE IP address allocation as well as other functions. The PDN Gateway 172 and the BM-SC 170 are connected to the IP Services 176. The IP Services 176 may include the Internet, an intranet, an IP Multimedia Subsystem (IMS), a PS Streaming Service (PSS), and/or other IP services. The BM-SC 170 may provide functions for MBMS user service provisioning and delivery. The BM-SC 170 may serve as an entry point for content provider MBMS transmission, may be used to authorize and initiate MBMS Bearer Services within a public land mobile network (PLMN), and may be used to schedule MBMS transmissions. The MBMS Gateway 168 may be used to distribute MBMS traffic to the base stations 102 belonging to a Multicast Broadcast Single Frequency Network (MBSFN) area broadcasting a particular service, and may be responsible for session management (start/stop) and for collecting eMBMS related charging information.

Referring again to FIG. 1, in certain aspects, the UE 104 and the base station 102 may also be configured to implement optimization techniques that maximize energy efficiency during multi-channel DL wireless communications (See 198). To maximize energy efficiency, the transmit circuitry of the base station 102 and the receive circuity of the UE 104 may be optimized jointly, thereby considering the communication system as a whole rather than independently and in isolation. Furthermore, the techniques discussed also allow for the UE 104 to utilize a (single and wideband) LNA in the receive circuitry of the UE 104 to amplify multi-channel DL transmissions from the base station 102 while still optimizing the energy efficiency.

To do this, the UE 104 and the base station 102 may communicate using a plurality of channels. More specifically, the base station 102 may be configured to transmit and the UE 104 may be configured to receive a plurality of DL transmission in the plurality of channels. Each DL transmission may be provided in a different one of the channels but may be transmitted simultaneously by the base station 102.

Accordingly, the plurality of channels may work in parallel and include a plurality of component carriers. To transmit the DL transmissions, the base station 102 may include transmit circuitry that generates and amplifies each of the DL transmissions so that the DL transmissions can be sent wirelessly to the UE 104. The transmit circuitry thus provides transmit power for the DL transmissions. Upon wireless reception by the UE 104, the LNA in the UE 104 may amplify the DL transmissions in the plurality of channels simultaneously since the plurality of channels share the LNA. In this manner, the DL transmissions are amplified so that other receive circuitry in the UE can process the DL transmissions.

To optimize the energy efficiency for multichannel DL communication, the base station 102 and/or the UE 104 may determine a set of parameters for the plurality of channels to maximize energy efficiency. In one configuration, the UE 104 may determine the set of parameters and communicate the set of parameters back to the base station 102. In another configuration, the base station 102 may determine the set of parameters and communicate the set of parameters to the UE 104. In another configuration, the base station 102 may determine some parameters while the UE 104 considers other parameters. Which configuration is utilized may depend on available resources and system characteristics.

In one configuration, to determine the set of parameters, the base station 102 and/or the UE 104 may fix the LNA gain, and utilize a sub-gradient method to optimize, under the fixed LNA gain, the transmit power for each of the plurality of channels to maximize the energy efficiency. For example, the base station 102 and/or the UE 104 may fix the LNA gain to the maximum LNA gain. To optimize an LNA gain of the LNA in the UE 104, the base station 102 and/or the UE 104 may perform a sweep of different LNA gain values for the LNA. More specifically, the base station 102 and/or the UE 104 may select the LNA gain from a set of LNA gains, which in one example is the maximum LNA gain. The base station 102 and/or the UE 104 then utilizes a sub-gradient method to optimize, under the selected LNA gain (e.g., the maximum LNA gain), the transmit power for each of the plurality of channels. The base station 102 and/or the UE 104 may repeat the selecting of the LNA gain and the utilizing of the sub-gradient method under the selected LNA gains, to find out the optimal LNA gain and the optimal transmit power for each of the plurality of channels to maximize the energy efficiency.

In some aspects, the repeating of the selecting and the utilizing may be through a linear search or may be through a bisection search. The characteristics of the system may be taken into account when maximizing the energy efficiency. For example, the set of parameters may be constrained by the maximum transmit power per channel at the base station 102, the maximum ADC input power at the UE 104, the maximum baseband SNR, and the maximum LNA gain of the shared LNA, as explained in further detail below.

Once the set of parameters is determined, the base station 102 and/or the UE 104 may configure the plurality of channels based on the set of parameters. For example, the base station 102 may set the transmit power of each of the channels of its transmit circuitry and the UE 104 may set the LNA gain as determined by the set of parameters when multi-channel DL transmissions are provided during normal operation. In this manner, the combined energy efficiency of transmit circuitry in the base station 102 and the receive circuitry in UE 104 is maximized. It should be noted that the base station 102 and the UE 104 may communicate instructions and information to one another so that the base station 102 and/or the UE 104 determine the set of parameters and configure the plurality of channels based on the set of parameters.

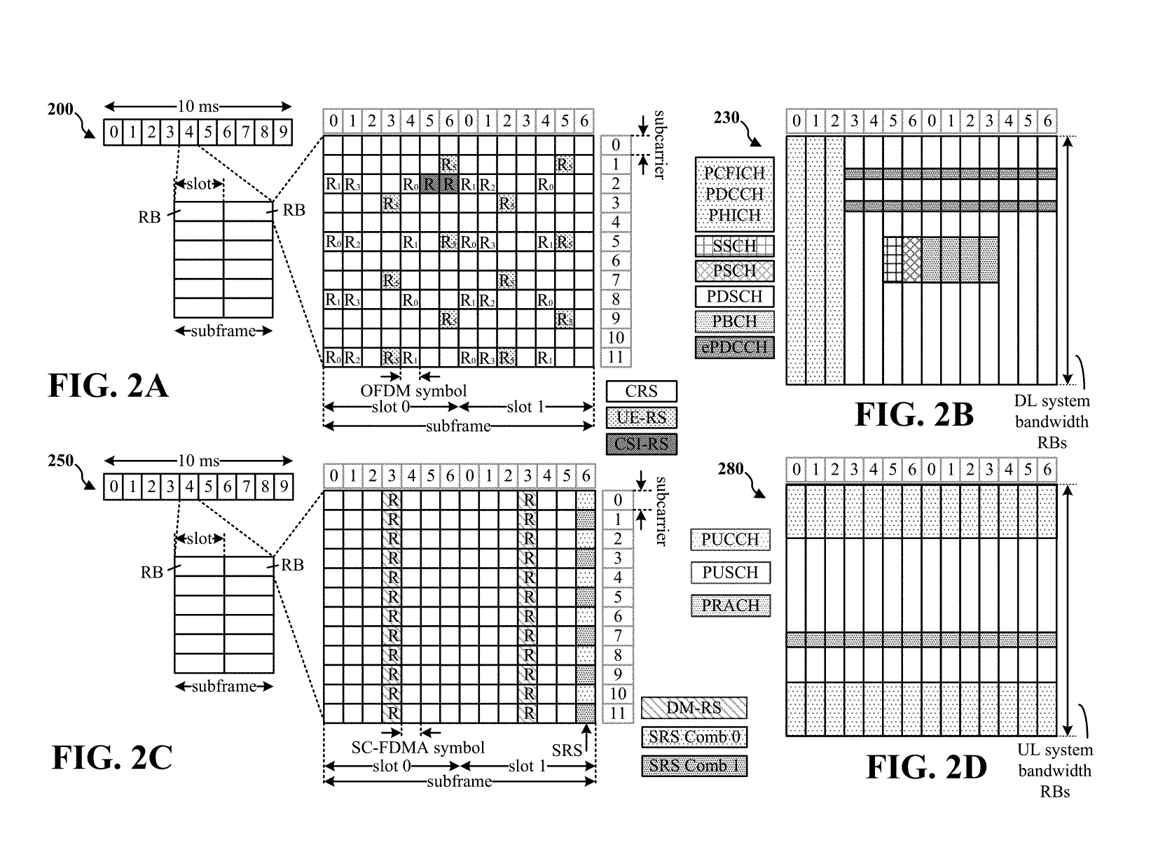

FIG. 2A is a diagram 200 illustrating an example of a DL frame structure in LTE. FIG. 2B is a diagram 230 illustrating an example of channels within the DL frame structure in LTE. FIG. 2C is a diagram 250 illustrating an example of an UL frame structure in LTE. FIG. 2D is a diagram 280 illustrating an example of channels within the UL frame structure in LTE. Other wireless communication technologies may have a different frame structure and/or different channels. In LTE, a frame (10 ms) may be divided into 10 equally sized subframes. Each subframe may include two consecutive time slots. A resource grid may be used to represent the two time slots, each time slot including one or more time concurrent resource blocks (RBs) (also referred to as physical RBs (PRBs)). The resource grid is divided into multiple resource elements (REs). In LTE, for a normal cyclic prefix, an RB contains 12 consecutive subcarriers in the frequency domain and 7 consecutive symbols (for DL, OFDM symbols; for UL, SC-FDMA symbols) in the time domain, for a total of 84 REs. For an extended cyclic prefix, an RB contains 12 consecutive subcarriers in the frequency domain and 6 consecutive symbols in the time domain, for a total of 72 REs. The number of bits carried by each RE depends on the modulation scheme.

As illustrated in FIG. 2A, some of the REs carry DL reference (pilot) signals (DL-RS) for channel estimation at the UE. The DL-RS may include cell-specific reference signals (CRS) (also sometimes called common RS), UE-specific reference signals (UE-RS), and channel state information reference signals (CSI-RS). FIG. 2A illustrates CRS for antenna ports 0, 1, 2, and 3 (indicated as R₀, R₁, R₂, and R₃, respectively), UE-RS for antenna port 5 (indicated as R₅), and CSI-RS for antenna port 15 (indicated as R). FIG. 2B illustrates an example of various channels within a DL subframe of a frame. The physical control format indicator channel (PCFICH) is within symbol 0 of slot 0, and carries a control format indicator (CFI) that indicates whether the physical downlink control channel (PDCCH) occupies 1, 2, or 3 symbols (FIG. 2B illustrates a PDCCH that occupies 3 symbols). The PDCCH carries downlink control information (DCI) within one or more control channel elements (CCEs), each CCE including nine RE groups (REGs), each REG including four consecutive REs in an OFDM symbol. A UE may be configured with a UE-specific enhanced PDCCH (ePDCCH) that also carries DCI. The ePDCCH may have 2, 4, or 8 RB pairs (FIG. 2B shows two RB pairs, each subset including one RB pair). The physical hybrid automatic repeat request (ARQ) (HARQ) indicator channel (PHICH) is also within symbol 0 of slot 0 and carries the HARQ indicator (HI) that indicates HARQ acknowledgement (ACK)/negative ACK (NACK) feedback based on the physical uplink shared channel (PUSCH). The primary synchronization channel (PSCH) is within symbol 6 of slot 0 within subframes 0 and 5 of a frame, and carries a primary synchronization signal (PSS) that is used by a UE to determine subframe timing and a physical layer identity. The secondary synchronization channel (SSCH) is within symbol 5 of slot 0 within subframes 0 and 5 of a frame, and carries a secondary synchronization signal (SSS) that is used by a UE to determine a physical layer cell identity group number. Based on the physical layer identity and the physical layer cell identity group number, the UE can determine a physical cell identifier (PCI). Based on the PCI, the UE can determine the locations of the aforementioned DL-RS. The physical broadcast channel (PBCH) is within symbols 0, 1, 2, 3 of slot 1 of subframe 0 of a frame, and carries a master information block (MIB). The MIB provides a number of RBs in the DL system bandwidth, a PHICH configuration, and a system frame number (SFN). The physical downlink shared channel (PDSCH) carries user data, broadcast system information not transmitted through the PBCH such as system information blocks (SIBs), and paging messages.

As illustrated in FIG. 2C, some of the REs carry demodulation reference signals (DM-RS) for channel estimation at the eNB. The UE may additionally transmit sounding reference signals (SRS) in the last symbol of a subframe. The SRS may have a comb structure, and a UE may transmit SRS on one of the combs. The SRS may be used by an eNB for channel quality estimation to enable frequency-dependent scheduling on the UL. FIG. 2D illustrates an example of various channels within an UL subframe of a frame. A physical random access channel (PRACH) may be within one or more subframes within a frame based on the PRACH configuration. The PRACH may include six consecutive RB pairs within a subframe. The PRACH allows the UE to perform initial system access and achieve UL synchronization. A physical uplink control channel (PUCCH) may be located on edges of the UL system bandwidth. The PUCCH carries uplink control information (UCI), such as scheduling requests, a channel quality indicator (CQI), a precoding matrix indicator (PMI), a rank indicator (RI), and HARQ ACK/NACK feedback. The PUSCH carries data, and may additionally be used to carry a buffer status report (BSR), a power headroom report (PHR), and/or UCI.

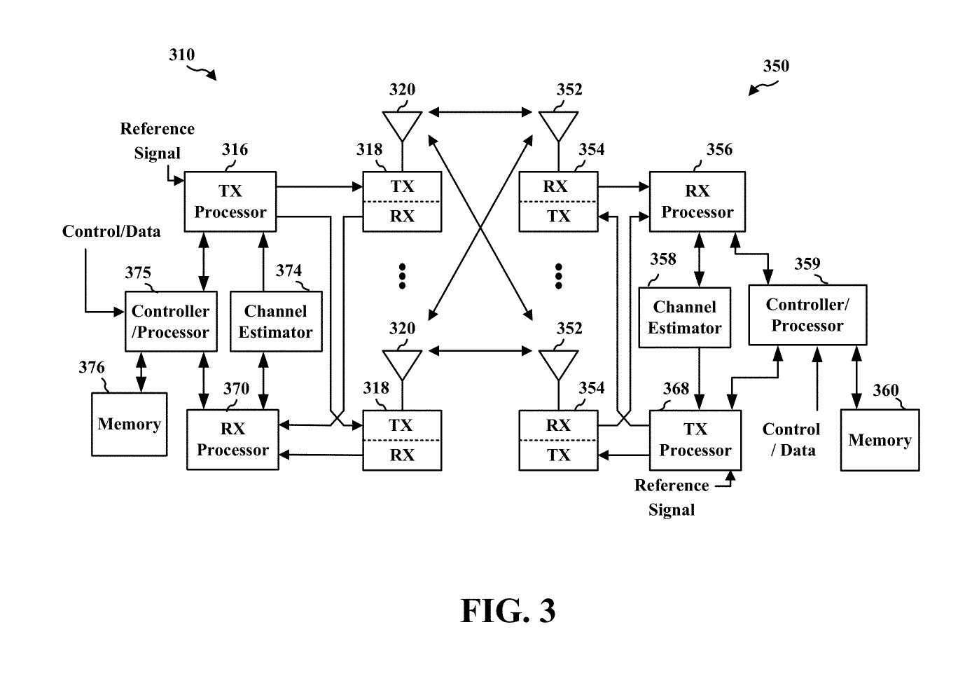

FIG. 3 is a block diagram of an eNB 310 in communication with a UE 350 in an access network. In the DL, IP packets from the EPC 160 may be provided to a controller/processor 375. The controller/processor 375 implements layer 3 and layer 2 functionality. Layer 3 includes a radio resource control (RRC) layer, and layer 2 includes a packet data convergence protocol (PDCP) layer, a radio link control (RLC) layer, and a medium access control (MAC) layer. The controller/processor 375 provides RRC layer functionality associated with broadcasting of system information (e.g., MIB, SIBs), RRC connection control (e.g., RRC connection paging, RRC connection establishment, RRC connection modification, and RRC connection release), inter radio access technology (RAT) mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer packet data units (PDUs), error correction through ARQ, concatenation, segmentation, and reassembly of RLC service data units (SDUs), re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through HARQ, priority handling, and logical channel prioritization.

The transmit (TX) processor 316 and the receive (RX) processor 370 implement layer 1 functionality associated with various signal processing functions. Layer 1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The TX processor 316 handles mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols may then be split into parallel streams. Each stream may then be mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 374 may be used to determine the coding and modulation scheme, as well as for spatial processing. The channel estimate may be derived from a reference signal and/or channel condition feedback transmitted by the UE 350. Each spatial stream may then be provided to a different antenna 320 via a separate transmitter 318TX. Each transmitter 318TX may modulate an RF carrier with a respective spatial stream for DL transmission.

At the UE 350, each receiver 354RX receives a signal through its respective antenna 352. Each receiver 354RX recovers information modulated onto an RF carrier and provides the information to the receive (RX) processor 356. The TX processor 368 and the RX processor 356 implement layer 1 functionality associated with various signal processing functions. The RX processor 356 may perform spatial processing on the information to recover any spatial streams destined for the UE 350. If multiple spatial streams are destined for the UE 350, they may be combined by the RX processor 356 into a single OFDM symbol stream. The RX processor 356 then converts the OFDM symbol stream from the time-domain to the frequency domain using a Fast Fourier Transform (FFT). The frequency domain signal comprises a separate OFDM symbol stream for each subcarrier of the OFDM signal. The symbols on each subcarrier, and the reference signal, are recovered and demodulated by determining the most likely signal constellation points transmitted by the eNB 310. These soft decisions may be based on channel estimates computed by the channel estimator 358. The soft decisions are then decoded and deinterleaved to recover the data and control signals that were originally transmitted by the eNB 310 on the physical channel. The data and control signals are then provided to the controller/processor 359, which implements layer 3 and layer 2 functionality.

The controller/processor 359 can be associated with a memory 360 that stores program codes and data. The memory 360 may be referred to as a computer-readable medium. In the UL, the controller/processor 359 provides demultiplexing between transport and logical channels, packet reassembly, deciphering, header decompression, and control signal processing to recover IP packets from the EPC 160. The controller/processor 359 is also responsible for error detection using an ACK and/or NACK protocol to support HARQ operations.

Similar to the functionality described in connection with the DL transmission by the eNB 310, the controller/processor 359 provides RRC layer functionality associated with system information (e.g., MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto TBs, demultiplexing of MAC SDUs from TBs, scheduling information reporting, error correction through HARQ, priority handling, and logical channel prioritization.

Channel estimates derived by a channel estimator 358 from a reference signal or feedback transmitted by the eNB 310 may be used by the TX processor 368 to select the appropriate coding and modulation schemes, and to facilitate spatial processing. The spatial streams generated by the TX processor 368 may be provided to different antenna 352 via separate transmitters 354TX. Each transmitter 354TX may modulate an RF carrier with a respective spatial stream for transmission.

The UL transmission is processed at the eNB 310 in a manner similar to that described in connection with the receiver function at the UE 350. Each receiver 318RX receives a signal through its respective antenna 320. Each receiver 318RX recovers information modulated onto an RF carrier and provides the information to a RX processor 370.

The controller/processor 375 can be associated with a memory 376 that stores program codes and data. The memory 376 may be referred to as a computer-readable medium. In the UL, the controller/processor 375 provides demultiplexing between transport and logical channels, packet reassembly, deciphering, header decompression, control signal processing to recover IP packets from the UE 350. IP packets from the controller/processor 375 may be provided to the EPC 160. The controller/processor 375 is also responsible for error detection using an ACK and/or NACK protocol to support HARQ operations.

The eNB 310 and the UE 350 may be configured to provide multichannel DL communication. To provide multichannel DL communication, the eNB 350 may transmit DL transmissions in parallel channels [i.e., where each DL transmission in a particular channel may include one or more RF DL signals (where each is transmitted at a different subcarrier)] to the UE 350. The UE 350 thus receives the aggregated DL transmissions and demultiplexes the parallel channels to demodulate each of the DL transmissions. In this manner, the eNB 310 and the UE 350 may achieve higher throughput for DL.

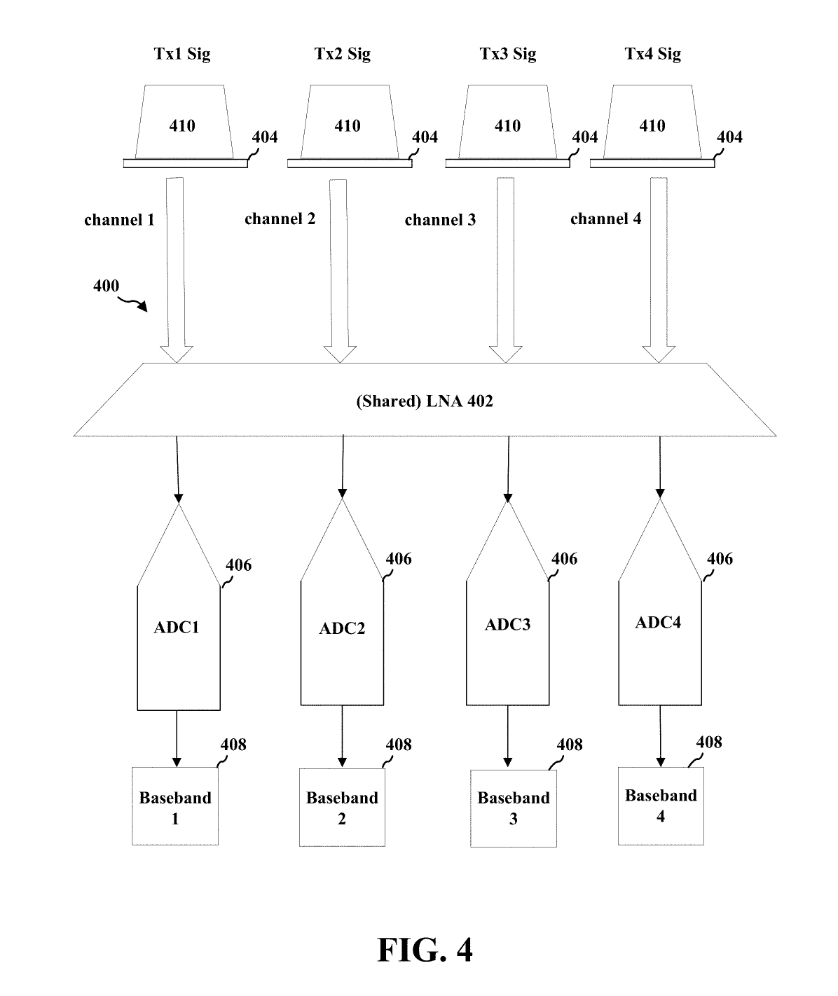

As explained in further detail below, the UE 350 has hardware designed to amplify the aggregated DL transmissions with reduced complexity and area consumption. Thus, the access network shown in FIG. 4 can handle greater numbers of parallel channels during multichannel DL communication at reduced cost. For example, the UE 310 may include an LNA configured to amplify aggregated DL transmissions in the parallel channels simultaneously (as explained in further detail below). In this manner, the UE 350 can amplify all of the DL transmissions with simplified hardware.

Furthermore, the eNB 310 and the UE 350 are also configured to maximize energy efficiency by optimizing the transmit power in the eNB 310 and the LNA gain in the UE 350. The optimization techniques disclosed herein can maximize energy efficiency even when the parallel channels experience different fading conditions. Furthermore, the optimization techniques may consider the combined energy efficiency of the eNB 310 and UE 350 to achieve the best system performance.

FIG. 4 illustrates example receive circuitry 400 that may be utilized by the UE 350 during multichannel DL communications. The receive circuitry 400 includes an LNA 402 shared by a plurality of parallel physical channels 404 (e.g., channel 1, channel 2, channel 3, channel 4), ADCs 406 (e.g., ADC1, ADC2, ADC3, AD4) where each ADC 406 is for a different one of the channels 404, and digital baseband circuits 408 (e.g., baseband 1, baseband 2, baseband 3, baseband 4) where each of the digital baseband circuits 408 is for a different one of the channels 404. The receive circuitry 400 may be provided in one or more of the receivers 354RX. For example, the LNA 402 may be provided in one of the receivers 354RX or may be shared by the receivers 354RX. In one implementation, each of the ADCs 406 and each of the digital baseband circuits 408 may be provided in a different one of the receivers 354RX. In another implementation, all of the ADCs 406 and all of the digital baseband circuits 408 may be provided in one of the receivers 354RX. In yet another implementation, the ADCs 406 and the digital baseband circuits 408 may be distributed within a (proper) subset of the receivers 354RX.

Each of the channels 404 include a different DL transmission 410 (Tx1 Sig, Tx2 Sig, Tx3 Sig, Tx4 Sig), where the DL transmissions 410 were generated by the eNB 310, amplified by transmit circuitry in one or more of the transmitters 318TX and then emitted wirelessly though RF electromagnetic emissions to the UE 350. For instance, one or more of transmitters 318TX may include power amplifiers that amplify the DL transmissions 410 so that the DL transmission 410 are emitted with sufficient power for reception by the UE 350.

In the example shown in FIG. 4, the channels 404 are provided in non-overlapping frequency ranges. Thus, while the DL transmissions may be provided in accordance to any telecommunication standards (e.g., LTE, WiFi, etc.), each of the channels 404 can be identified by a different component carrier frequency within the particular channels 404 frequency range. Each of the DL transmissions 410 may be provided in a particular channel 404 and thus the channels 404 have a bandwidth at least as large as the bandwidth of the DL transmissions 410.

When the RF electromagnetic emissions are received by one or more of the antennas 326, the DL transmissions 410 may be generally weak given the attenuation experienced during wireless communication. Thus, as shown in FIG. 4, the DL transmissions 410 in the parallel channels 404 are amplified simultaneously by the LNA 402. Thus, the DL transmissions 410 are aggregated at the LNA input of the LNA 402, which amplifies the aggregated DL transmissions 410 in accordance with a variable LNA gain of the LNA 402. The number of channels 404 that share the LNA 402 is denoted as N (e.g., in this example 4 but it may be any number so long as the LNA can provide adequate amplification across the channels that share the LNA 402). The DL transmissions 410 are then demultiplexed so that each is provided to a different ADC converter 406. Each of the ADCs 406 sample and convert the DL transmissions 410 from analog to digital DL transmissions. Once converted by the ADCs 406, each of the DL transmission 410 is provided to one of the digital baseband circuits 408. The digital baseband circuits 408 may be configured to digitally down convert the DL transmission 410 to baseband so that the RX processor 356 may provide decode and extract information from the DL transmission 410.

Referring now to FIG. 3 and FIG. 4, a joint transmit power and LNA gain optimization framework may be used to maximize energy efficiency during multichannel DL transmissions 410. More specifically, the eNB 310 and/or the UE 350 may be configured to maximize energy efficiency by tuning system parameters including transmit power provided by the eNB 310 to each of the channels 404 and the variable LNA gain of the LNA 402 in the UE 350. Thus, the eNB 310 and/or the UE 350 determine a set of parameters for the plurality of channels 404 to maximize energy efficiency.

The energy efficiency may be measured by the number of transmitted bits per unit of energy. In one aspect, the energy efficiency may be defined as a ratio between spectral efficiency (SE) and consumed power and may be approximated by:

$$U ( P , G ) = \frac{{\sum }_{k = 1}^{N} {R}_{k}}{( Pc + {\sum }_{k = 1}^{N} {P}_{k} / η )} \qquad ( 1 )$$

U is the energy efficiency.

N corresponds to the number of channels 404 (e.g., N=4 in the specific example given in FIG. 4 but may be any number of channels in other implementations).

k is an integer that identifies a specific channel 404.

P is a transmit power vector, where P=[P₁, P₂, . . . P_{N}] so that the vector components of P are the transmit power (i.e., noted generically as Pₖ) of each of the channels 404.

G is the variable LNA gain of the LNA 402, where G=10^{G}^{_{dB}}/10 and G_{dB} is the variable LNA gain in the dB domain.

Rₖ is the SE of each channel 404 expressed a modified Shannon capacity, as explained below.

P_{c} denotes the DC portion of the power consumed by the transmitter(s) 318TX and the receiver(s) 354 during a multichannel DL communication.

η is the power amplifier efficiency.

In one aspect, to determine the set of parameters, the LNA gain and the transmit power may be selected so as to maximize equation (1). It should be noted that equation (1) may take into account the path loss experienced by each of the channels 404. For example, a WINNER II path loss model under 5GHz carrier frequency may be assumed to approximate the path loss in dB with the equation:

Dₖ^{dB}=46+20 log 10(dₖ)+Vₖ (2)

Dₖ is the path loss of each channel 404 (and Dₖ^{dB} is the path loss in dB).

dₖ is a distance in meters.

Vₖ denotes shadow fading of each channel 404 that follows log-normal distribution.

The path loss may be one of the factors utilized to determine the SE of each channel (i.e., Rₖ).

The SE at the kth channel is derived from the SNR (i.e., Γₖ) of each channel 404 via a modified Shannon capacity:

Rₖ=Aₛ log(1+A_{d}*Γₖ) when Γₖ<Γₘₐₓ (3)

Rₖ=Aₛ log(1+A_{d}*Γₘₐₓ) when Γₖ≧Γₘₐₓ (4)

Γₖ is the resultant SNR at each channel 404. Here Aₛ represents spatial multiplexing gain from multiple spatial streams. A_{d} is the diversity gain via multiple antennas 320, 352 and can be fitted offline using data obtained from link adaptation simulations. Γₘₐₓ is the maximum achievable baseband SNR at the receiver(s) 354, given the phase noise and IQ mismatch.

In one aspect, Γₖ is derived as:

Γₖ=(GPₖDₖ)/(GN_{F}σ_{N}²+σ_{q}²) (5)

N_{F} is a noise figure of the LNA 402.

σ_{N}² is RF thermal noise.

σ_{q}² is ADC quantization noise.

Note that for a given LNA gain G, there is a one to one mapping between Pₖ and Rₖ. An SE vector R under configuration P and G can thus be provided where R=[R₁, R₂, . . . R_{N}]. More specifically, P is bijective with R (and therefore also injective and surjective with R). As a result, energy efficiency U can also be noted as U(R,G). U(P,G) and U(R,G) are thus exchangeable throughout this disclosure to describe the energy efficiency. U(G) may thus denote the maximum energy efficiency under all feasible power vectors P (or equivalently under all feasible SE vectors R) and a given LNA gain G.

The components in the system have operational limitations that may be considered in order to accurately optimize the energy efficiency of the system. Thus, to determine the LNA gain and the transmit power that maximizes energy efficiency, the eNB 310 and/or the UE 310 may constrain solutions that maximize the energy efficiency by these physical constraints. For example, the variable LNA gain of the LNA 402 may vary between a maximum LNA gain (i.e., G_{dBmax} in dB domain) and a minimum LNA gain (i.e., G_{dBmin} in the dB domain), given the limitations of the LNA 402. The transmit power (i.e., Pₖ) of each channel 404 may be constrained to a maximum power value (i.e., Pₘₐₓ). The maximum power value may correspond to the power limitations of the power amplifier(s) in the transmitters 318TX and/or to a maximum power spectral density (PSD) of the transmitters 318TX. Furthermore, the ADCs 406 may not operate correctly if driven into saturation. Accordingly, the power of each channel 404 at the input of its respective ADC 406 may be constrained to a maximum ADC input power (i.e., Pₘₐₓ^{ADC}). Finally, phase noise and IQ mismatch can limit the baseband SNR. Accordingly, the baseband SNR of each of the channels 404 may be constrained by a maximum baseband SNR (i.e., Γₘₐₓ).

In one aspect, equation (1) is constrained by the maximum transmit power of each channel 406, and is jointly constrained by the maximum transmit power of the power amplifier(s) in the eNB 350, maximum ADC input power of the ADCs 406, the maximum baseband SNR, and the maximum LNA gain.

Accordingly, equation (1) above is constrained such that:

G_{dBmin}≦G_{dB}≦G_{dBmax} (6)

Pₖ≦Pₘₐₓ (7)

GPₖDₖ+GN_{F}σ_{N}²≦Pₘₐₓ^{ADC}(GPₖDₖ+GN_{F}σ_{N}² is input power at each ADC 406) (8)

The transmit power may be further constrained by the maximum baseband SNR. For example, given (3), (4), (6), (7), (8) and Γₘₐₓ, Pₖ may be further constrained such that:

Pₖ≦(GN_{F}σ_{N}²+σ_{q}²)Γₘₐₓ/GDₖ (9)

When equation (1) is maximized under the constraints of equation (6)-(9), each Rₖ is a non-decreasing function of G and P is defined as a feasible vector for a given G value.

To determine the LNA gain and the transmit power of each of the channels 404 that maximizes energy efficiency, the eNB 310 and/or the UE 350 may be configured to fix the LNA gain and then utilizes a sub-gradient method to optimize, under the fixed LNA gain, a transmit power for each of the plurality of channels to maximize the energy efficiency. For example, the variable LNA gain may be fixed to the maximum LNA gain (corresponding to G_{dBmax}).

With regards to energy efficiency defined by equation (1), it can be shown that, when the variable LNA gain G is fixed to a particular LNA gain value, equation (1) is an objective function and in particular a quasi-concave function over the SE vector R.

Given the fixed LNA gain value, the transmit power is thus first limited by:

P_{k,1}^{max}(G)=Pₘₐₓ (10)

Secondly, given a fixed LNA gain value, ADC power input further limits the transmit power by:

P_{k,2}^{max}(G)=(Pₘₐₓ^{ADC}−GN_{F}σ_{N}²)/GDₖ (11)

Thirdly, given a fixed LNA gain value, due to maximum baseband SNR (caused by phase noise and IQ mismatch), the transmit power is further limited by:

P_{k,3}^{max}(G)=[Γₘₐₓ(GN_{F}σ_{N}²+σ_{q}²)]/GDₖ (12)

By jointly considering all above conditions, maximum transmit power at the kth channel 404 may be calculated as:

Pₖ^{M}(G)=min {P_{k,1}^{max}(G), P_{k,2}^{max}(G), P_{k,3}^{max}(G) (13)

The SE under power value Pₖ^{M}(G) is designated as Rₖ^{M}(G). Thus, Pₖ^{M}(G) is P_{k,1}^{max}(G), P_{k,2}^{max}(G), or P_{k,3}^{max}(G) under different parameter spaces. The parameter spaces may be given by:

Pₖ^{M}(G)=P_{k,1}^{max}(G), when G≦Pₘₐₓ^{ADC}/(DₖPₘₐₓ+N_{F}σ_{N}²) and G≦Γₘₐₓσ_{q}²/(DₖPₘₐₓ−N_{F}σ_{N}²Γₘₐₓ). (14)

Pₖ^{M}(G)=P_{k,2}^{max}(G), when G≧Pₘₐₓ^{ADC}/(DₖPₘₐₓ+N_{F}σ_{N}²) and G≧(Pₘₐₓ^{ADC}−σ_{q}²Γₘₐₓ)/(N_{F}σ_{N}²(Γₘₐₓ+1)) (15)

Pₖ^{M}(G)=P_{k,3}^{max}(G), when G≧Γₘₐₓσ_{q}²/(DₖPₘₐₓ−N_{F}σ_{N}²Γₘₐₓ) and G≦(Pₘₐₓ^{ADC}−σ_{q}²Γₘₐₓ)/(N_{F}σ_{N}²(Γₘₐₓ+1)). (16)

Given equation (10)-(16) and the fixed LNA value, the eNB 310 and/or UE 350 may utilize a sub-gradient method to optimize equation (1) using a sub-gradient direction specified via a sub gradient metric. More specifically, for the SE, Rₖ, at the kth channel 404:

$$\begin{matrix}\frac{\partial U ( R , G )}{\partial {R}_{k}} = ( {P}_{c} + {P}_{sum} - \frac{\partial {P}_{sum}}{\partial {R}_{k}} {\sum }_{i = 1}^{N} {R}_{i} ) / {( {P}_{c} + {P}_{sum} )}^{2} & ( 17 ) \\ {P}_{sum} = {\sum }_{k = 1}^{N} ( {P}_{k} / η ) & ( 18 )\end{matrix}$$

Given equations (17) and (18), a metric is thus given by:

$$\frac{\partial {P}_{sum}}{\partial {R}_{k}} = [ ( {GN}_{F} {σ}_{N}^{2} + {σ}_{q}^{2} ) / ( η {A}_{s} {A}_{d} {GD}_{k} ) ] exp ( {R}_{k} / {A}_{s} ) \qquad ( 19 )$$

Thus, a sub gradient metric can thus be defined over vector R as

$$∇ U ( R , G ) = [ \frac{\partial U}{\partial {R}_{1}} , … , \frac{\partial U}{\partial {R}_{N}} ] .$$

In one example, a sub gradient method may be performed with the sub gradient metric to determine the transmit power that optimizes the energy efficiency, given the fixed LNA gain value. Among others, example procedures of the sub gradient method may include:

Procedure 1 (Initialization): Initialize index l so that l=1. Initialize the SE of the kth channel 404 Rₖ^{l}(G) as Rₖ^{M}(G) where Rₖ^{M}(G) is based on equation (13). Set initial optimal value as Uₒₚₜ(G)=U(R¹, G).

Procedure 2: g_{I}=∇U(R¹, G) and update spectral efficiency as R^{l+1}=R¹+tₗg_{I} where tₗ is a step size as explained in further detail below.

Procedure 3: Project the efficiency vector R^{l+1} into a feasible region. More specifically, if Rₖ^{l+1}>Rₖ^{M}(G) then Rₖ^{l+1}=Rₖ^{M}(G) and if Rₖ^{l+1}<Rₖ^{M}(G) then Rₖ^{l+1}=0.

Procedure 4: Determine U(R^{l+1},G). If U(R^{l+1},G)>Uₒₚₜ(G) then Uₒₚₜ(G) is set to U(R^{l+1},G) and R^{opt}=R^{l+1}.

Procedure 5: If l=Lmax (see below), then terminate. Otherwise set l=l+b 1.

In this manner, the transmit power of each channel 404 that maximizes the energy efficiency given the fixed LNA gain can be determined. For example, if the variable LNA gain is fixed to the maximum LNA gain, the optimal transmit power of each channel 406 that maximizes energy efficiency when the LNA gain is fixed to the maximum LNA gain may be determined.

In one aspect, the eNB 310 and/or the UE 350 may perform a linear search to optimize both the transmit power and the LNA gain. More specifically, the procedures of the sub gradient method may be repeated by sweeping through all of the LNA gain values of the LNA. Thus, for each possible LNA value, the LNA gain is fixed to a selected LNA value and the procedures of the sub gradient method may be repeated for the selected LNA value. Every LNA gain value is thus selected (assuming that the LNA gain values of the LNA 402 are discrete) and the procedures are thus repeated for each LNA gain value. In this manner, the eNB 310 and/or the UE 350 may be configured to determine the LNA gain of the LNA 402 and the transmit power of each channel 406 that achieve global optimization of the energy efficiency.

With regards to the step size (i.e., tₗ) and Lₘₐₓ (which determines the number of iterations taken during Procedures 1-4 for a fixed LNA value), the step size tₗ may be determined based on a divergent series, such as:

tₗ→0, and Σₗ₌₁^{∞}tₗ=∞ (20)

Alternately, the step size tₗ can be determined by a series:

Σₗ₌₁^{∞}tₗ²<∞, and Σₗ₌₁^{∞}tₗ=∞ (21)

Proposed optimization terminates at the maximum iteration Lₘₐₓ. In general, the larger Lₘₐₓ the greater the convergence accuracy. However, given the linear search described above and divergent series in equation (20) and (21), the convergence accuracy of the linear search has an upper bound once Lₘₐₓ reaches a particular value. More specifically, the convergence result after Lₘₐₓ iterations can be expressed as:

R^{L}^{ₘₐₓ}(G)=arg_{R}_{¹}_{,1≦l≦L}_{ₘₐₓ} max U(R¹,G) (23)

Equation (20) can be shown to converge at some 1. Given the divergent series, it can be shown that equation (23) has an upper bound expressed as:

r(S)≦1/2(D²+Σⱼ₌₁^{L}^{ₘₐₓ}tⱼ²)/Σⱼ₌₁^{L}^{ₘₐₓ}tⱼ where D:=diam(R) and S:={R: U(R, G)<U_{L}_{ₘₐₓ}(G)}. (24)

Thus, the series in equation (21) may result in weak convergence. Furthermore, given equation (24) the convergence accuracy has an upper bound, which is expressed as:

r(S)≦cLₘₐₓ^{-1/2}, where c=(2⁻¹+2^{-3/2})└D²/a+(1+ln(2))a┘when tₗ=al^{-1/2}and a>0. (25)

Lₘₐₓ and tₗ can thus be provided in accordance with the upper bound of the convergence accuracy.

In another aspect, the eNB 310 and/or the UE 350 may perform a bisection search to optimize the LNA gain with the transmit power determined by the sub gradient procedures. This strategy is based on equation (1) being an objective and concave function over the LNA gain when the transmit power vector is determined by the sub gradient procedures, and optimal LNA gain under concave function has

$$\frac{\partial U ( G )}{\partial G} = 0.$$

The bisection search is to find the LNA gain value with

$$\frac{\partial U ( G )}{\partial G} = 0$$

between the maximum and the minimum LNA gain range. In the bisection search, the LNA gain may initially be provided at the mid-point LNA value of maximum and minimum LNA gain values, and the procedures of the sub gradient method may be performed under the mid-point LNA gain. If the mid-point LNA gain results in

$$\frac{\partial U ( G )}{\partial G} > 0 ,$$

then the LNA range is reduced to be between mid-point LNA gain value and maximum LNA gain value, and then the bisection search can be repeated for the mid LNA value of that reduced LNA range. If the mid-point LNA gain results in

$$\frac{\partial U ( G )}{\partial G} < 0 ,$$

then the LNA range is reduced and set between minimum LNA gain value and mid-point LNA gain value, and then the bisection search can be repeated for the mid LNA value of that reduced LNA range. The interval can be cut in half in accordance with the bisection search until the mid-point LNA gain value results in

$$\frac{\partial U ( G )}{\partial G} = 0$$

or the reduced LNA range is small enough, and the bisection search is thereby stopped. As such, the bisection search only needs log₂(G_{dBmax}-G_{dBmin}) rounds of searching before the optimal LNA gain and the optimal transmit power are found. The bisection search can be used both when the variable LNA gain is programmable to discrete values and when the variable LNA gain is continuous. Furthermore, the bisection method guarantees that the optimal LNA gain and the optimal transmit power are found. Furthermore, the bisection method significantly reduces the complexity of finding the optimal LNA gain and the optimal transmit power.

Once the set of parameters are determined, the eNB 310 and/or the UE 350 may then configure the channels 404 based on the set of parameters. For instance, if the eNB 310 determined the set of parameters, the eNB 310 may set the transmitter(s) 318TX so that the power amplifier(s) amplify DL transmissions in the parallel channels at the determined optimal transmit power of each of the channels 404. The eNB 310 may also transmit instructions to the UE 350 that indicate the determined optimal LNA gain. In response, the UE 350 provides the variable LNA gain of the LNA 402 at the determined optimal LNA gain.

On the other hand, if the UE 350 determined the set of parameters, the UE 350 provides the variable LNA gain of the LNA 402 at the determined optimal LNA gain. The UE 350 may then transmit instructions to the eNB 310 that indicate the determined optimal transmit power. In response, the eNB 310 may set the transmitter(s) 318TX so that the power amplifier(s) amplify DL transmissions in the parallel channels at the determined optimal transmit power.

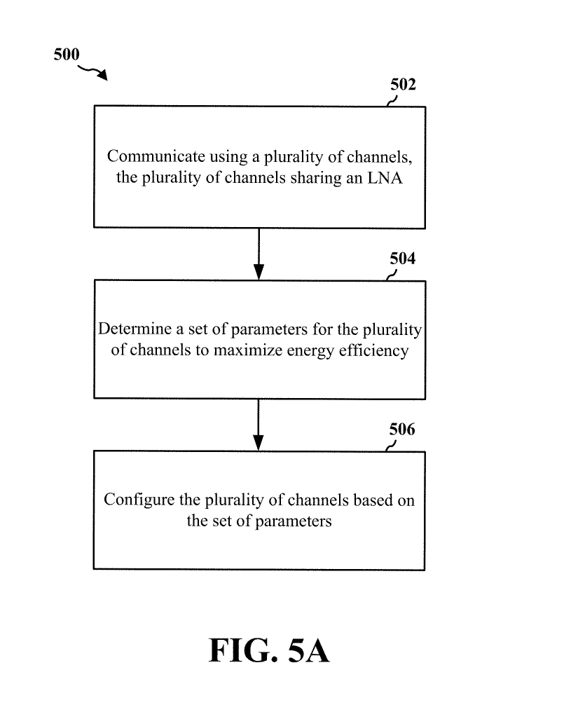

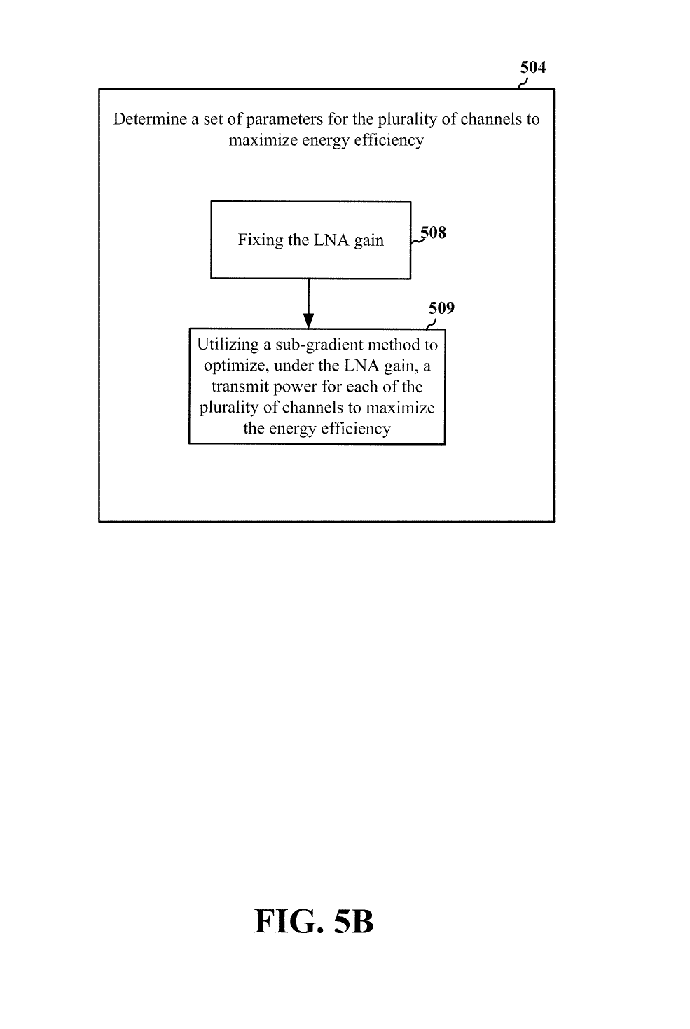

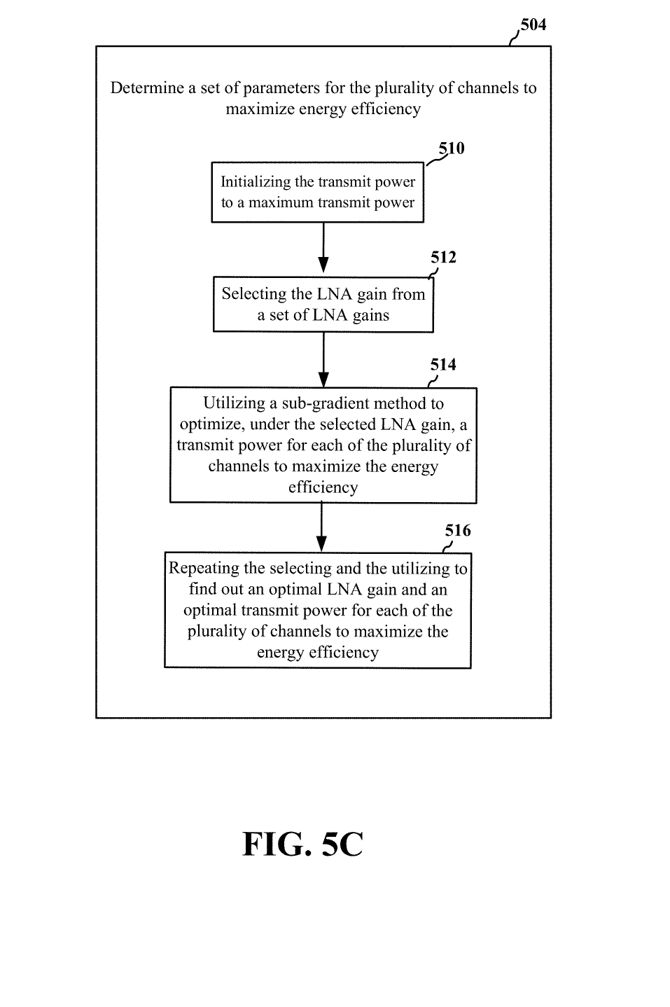

FIGS. 5A, 5B, and 5C illustrate aspects of a flowchart 500 of a method of wireless communication. The method may be performed by an apparatus, which may be UE and/or eNB (e.g., the UE 104, 350, the base station 102, 310, the apparatus 602/602′). In FIG. 5A, at 502, the apparatus may communicate using a plurality of channels. The plurality of channels may share an LNA. In one aspect, the plurality of channels may work in parallel and the plurality of channels may include a plurality of component carriers.

At 504, the apparatus may determine a set of parameters for the plurality of channels to maximize energy efficiency. In one configuration, the set of parameters may be constrained by a maximum transmit power per channel, a maximum ADC input power, a maximum baseband SNR, and a maximum LNA gain. In some aspects, the energy efficiency may be measured by a number of transmitted bits per unit energy and may be a combined energy efficiency of transmit circuitry in a base station and receive circuitry in a UE. The receive circuitry of the UE may include the LNA.

At 506, the apparatus may configure the plurality of channels based on the set of parameters. For instance, if the apparatus is a base station, the base station may set its transmitter(s) so that its power amplifier(s) amplify DL transmissions in the parallel channels at the determined optimal transmit power. The base station may also transmit instructions to a UE that indicate the determined optimal LNA gain. In response, the UE provides a variable LNA gain of an LNA at the determined optimal LNA gain.

On the other hand, if the apparatus is a UE, the UE provides the variable LNA gain of the LNA at the determined optimal LNA gain. The UE may then transmit instructions to the eNB that indicate the determined optimal transmit power. In response, the eNB may set the transmitter(s) so that the power amplifier(s) amplify DL transmissions in the parallel channels at the determined optimal transmit power.

As illustrated in FIG. 5B, in one aspect, to determine the set of parameters at 504, the apparatus may perform 508-509. More specifically, the apparatus fixes the LNA gain at 508. For example, the LNA gain may be fixed to a maximum LNA gain of the LNA. At 509, the apparatus utilizes a sub-gradient method to optimize, under the LNA gain, a transmit power for each of the plurality of channels to maximize the energy efficiency.

As illustrated in FIG. 5C, in another aspect, to determine the set of parameters at 504, the apparatus may perform 510-516. Initially, the apparatus may fix the transmit power to a maximum transmit power at 510. Next, the apparatus selects an LNA gain from a set of LNA gains at 512. At 514, the apparatus utilizes a sub-gradient method to optimize, under the selected LNA gain, a transmit power for each of the plurality of channels to maximize the energy efficiency. The apparatus repeats the selecting and the utilizing to find out an optimal LNA gain and an optimal transmit power for each of the plurality of channels to maximize the energy efficiency at 516. Examples of 510-516 are discussed above with respect to FIG. 3 and FIG. 4 and the sub gradient method.

In one configuration, the apparatus may perform a linear search at 516. For example, the apparatus may sweep through all of the possible LNA gains and perform sub-gradient procedures for each of the LNA gains to find the optimal LNA gain and optimal transmit power, as explained above with respect to FIG. 3 and FIG. 4. In another configuration, the apparatus may perform a bisection search at 516. For example, the apparatus may use the bisection search method to find the optimal LNA gain and the optimal transmit power, as explained above with respect to FIG. 3 and FIG. 4.

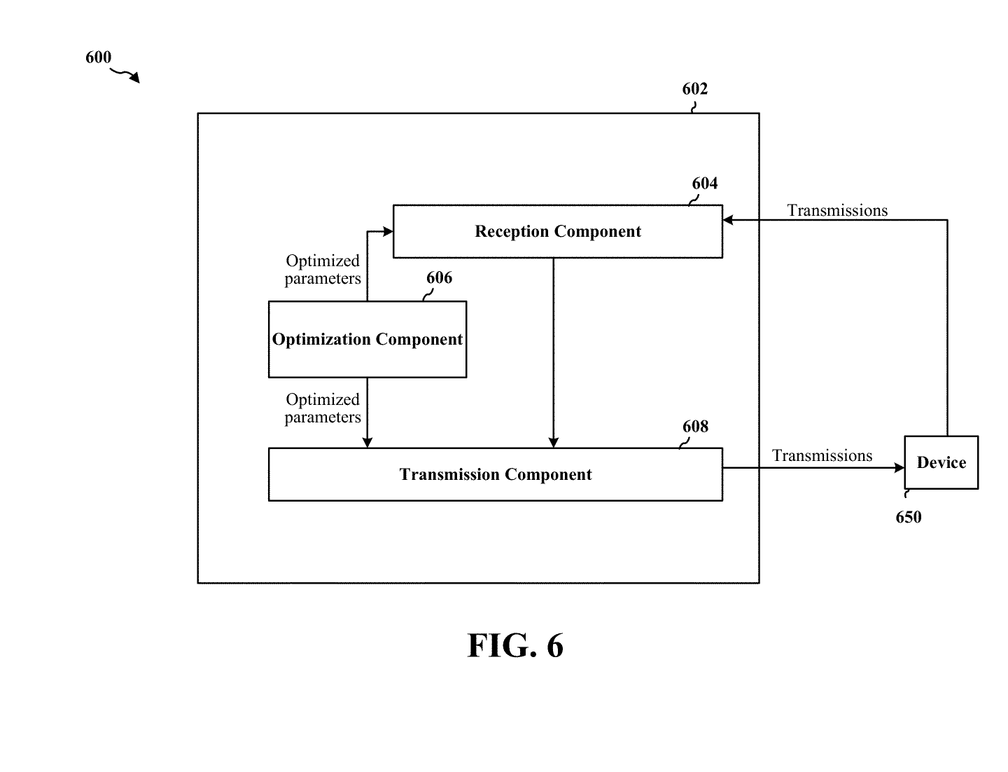

FIG. 6 is a conceptual data flow diagram 600 illustrating the data flow between different means/components in an exemplary apparatus 602. The apparatus 602 may be a UE (e.g., UE 104 or UE 350) or a base station (e.g., base station 102 or eNB 310). The apparatus 602 may include a reception component 604 that receives transmissions from the device 650. If the apparatus 602 is a UE, the reception component 604 may receive DL transmission from the device 650 through multiple channels simultaneously. In this case, the apparatus 602 may perform the operations related to 502 in FIG. 5 with the reception component 604. Furthermore, the apparatus 602 may include an LNA (e.g., the LNA 402 shown in FIG. 4) associated with the reception component 604, wherein the plurality of channels share the LNA. The apparatus 602 may include a transmission component 608 that transmits transmissions to the device 650. If the apparatus 602 is a base station, the transmission component 608 transmits DL transmissions to the device 650 through multiple channels. In this case, the apparatus 602 may perform the operations related to 502 in FIG. 5 with the transmission component 608. Furthermore, in this case, the device 650 would include an LNA (e.g., the LNA 402 shown in FIG. 4), wherein the plurality of channels share the LNA. The plurality of the channels may work in parallel and/or may include a plurality of component carriers.

The apparatus 602 may include an optimization component 606 that determines a set of parameters for multiple channels to maximize energy efficiency. The optimization component 606 may send optimized parameters to the reception component 604 and the transmission component 608 to configure the reception and/or transmission of DL transmissions. In one configuration, the optimization component 606 may perform the operations described above with reference to 504 in FIG. 5. For example, to perform 504, the optimization component 606 may be configured to perform 508-509, which is related to the sub-gradient method under the fixed LNA gain. In another example, to perform 504, the optimization component 606 may be configured to perform 510-516, which is related to the sub-gradient method. In one aspect, the optimization component 606 performs 516 through a linear search. In another aspect, the optimization component 606 performs 516 though a bisection search. The optimization component 606 may measure the energy efficiency by a number of transmitted bits per unit of energy. Furthermore, the optimization component 606 may constrain the set of parameters by a maximum transmit power per channel, a maximum ADC input power, a maximum baseband SNR, and a maximum LNA gain.

The optimization component 602 may be further configure the plurality of channels based on the set of parameters, as described in 506 of FIG. 5. For example, the optimization component 606 may output optimized parameters to the transmission component 604 if the apparatus is a base station. The transmission component 604 is associated with a transmitter. The optimized parameters may include an optimized transmit power for each of the channels. The transmission component 604 may set the transmitter so that the DL transmission in each of the channels is transmit to the device 650 at the optimized transmit power of the channel. In addition, the optimization component 606 may output an optimized LNA gain to the transmission component 608. The transmission component 608 may then generate a transmission with an instruction that the device 650 set the LNA to the optimized LNA gain. In this manner, the device 650 may receive the transmission and set the LNA to the optimized LNA gain.

On the other hand, the apparatus may be a UE. In this case, the optimization component 606 outputs the optimized parameters to the transmission component 604 and the reception component 608. For example, the optimization component 606 may output an optimized transmit power for each of the channels to the transmission component 608. The transmission component 608 may then generate one or more transmission with one or more instructions that the device 650 set a transmitter in the device 650 so that DL transmissions in each of the channels are each provided at the optimized transmit power of each of the channels. The optimization component may also output an optimized LNA gain to the reception component 604. The reception component 604 may then set the LNA gain of the LNA (shared by the channels) to the optimal LNA gain. In this manner, DL transmissions in the plurality of channels from the device 650 by the LNA in accordance with the optimized LNA gain.

The apparatus may include additional components that perform each of the blocks of the algorithm in the aforementioned flowcharts of FIG. 5. As such, each block in the aforementioned flowcharts of FIG. 5 may be performed by a component and the apparatus may include one or more of those components. The components may be one or more hardware components specifically configured to carry out the stated processes/algorithm, implemented by a processor configured to perform the stated processes/algorithm, stored within a non-transitory computer-readable medium for implementation by a processor, or some combination thereof

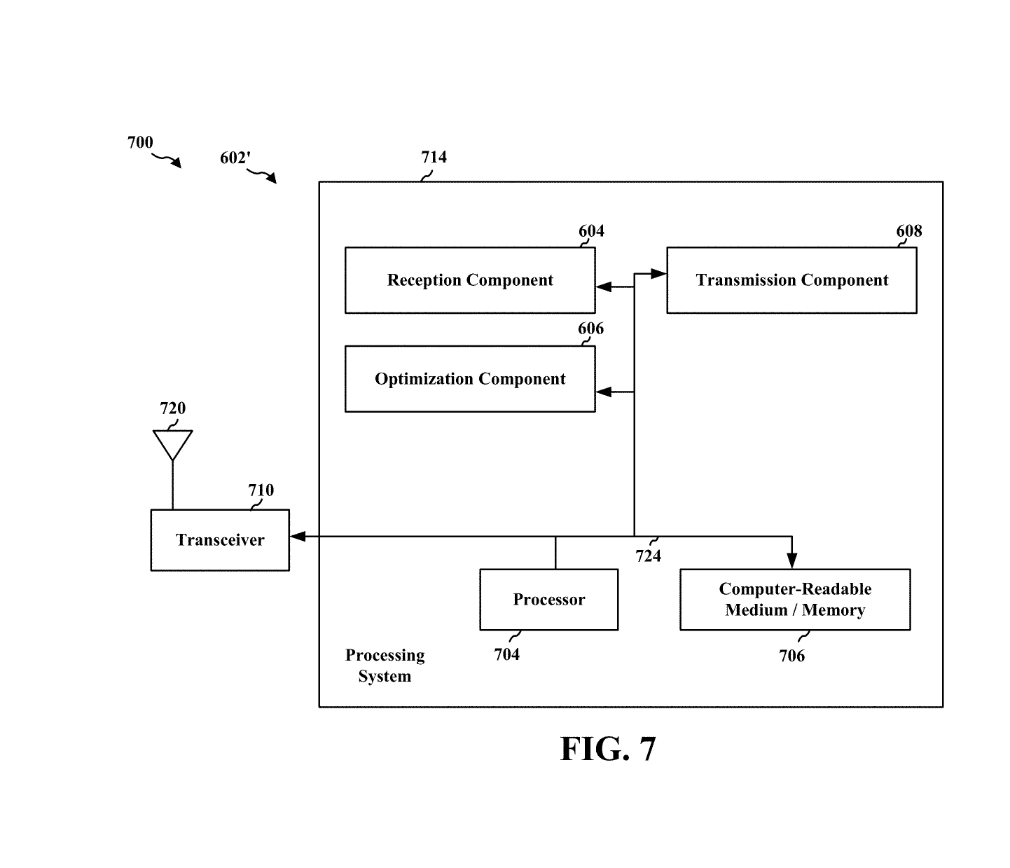

FIG. 7 is a diagram 700 illustrating an example of a hardware implementation for an apparatus 602′ employing a processing system 714. The apparatus 602′ may be a UE (e.g., UE 104 or UE 350) or a base station (e.g., base station 102 or eNB 310). The processing system 714 may be implemented with a bus architecture, represented generally by the bus 724. The bus 724 may include any number of interconnecting buses and bridges depending on the specific application of the processing system 714 and the overall design constraints. The bus 724 links together various circuits including one or more processors and/or hardware components, represented by the processor 704, the components 604, 606, 608, and the non-transitory computer-readable medium/memory 706. The bus 724 may also link various other circuits such as timing sources, peripherals, voltage regulators, and power management circuits, which are well known in the art, and therefore, will not be described any further.

The processing system 714 may be coupled to a transceiver 710. If the apparatus 602′ is a UE, receive circuitry in the transceiver 710 may include an LNA shared by the channels. The LNA gain may be set by the reception component 604, as explained above. For example, the receive circuit shown in FIG. 4 may be provided in the transceiver 710. On the other hand, if the apparatus 602 is a base station, the transceiver includes transmit circuitry that transmits DL transmissions in the plurality of channels. The transmit circuitry may include a power amplifier(s) that provides each DL transmissions in each of the channels at a transmit power for each of the channels. The transceiver 710 is coupled to one or more antennas 720. The transceiver 710 provides a means for communicating with various other apparatus over a transmission medium. The transceiver 710 receives transmissions from the one or more antennas 720, extracts information from the received transmissions and provides the extracted information to the processing system 714, specifically the reception component 604. In addition, the transceiver 710 receives information from the processing system 714, specifically the transmission component 608, and based on the received information, generates a transmissions to be applied to the one or more antennas 720. The processing system 714 includes a processor 704 coupled to a non-transitory computer-readable medium/memory 706. The processor 704 is responsible for general processing, including the execution of software stored on the non-transitory computer-readable medium/memory 706. The software, when executed by the processor 704, causes the processing system 714 to perform the various functions described supra for any particular apparatus. The computer-readable medium/memory 706 may also be used for storing data that is manipulated by the processor 704 when executing software.

The processing system 714 further includes at least one of the components 604, 606, 608. The components may be software components running in the processor 704, resident/stored in the computer readable medium/memory 706, one or more hardware components coupled to the processor 704, or some combination thereof. The processing system 714 may be a component of the eNB 310 and may include the memory 376 and/or at least one of the TX processor 316, the RX processor 370, and the controller/processor 375. The processing system 714 may be a component of the UE 350 and may include the memory 360 and/or at least one of the TX processor 368, the RX processor 356, and the controller/processor 359.

In one configuration, the apparatus 602/602′ for wireless communication may include means for communicating using a plurality of channels. Additionally, the apparatus 602/602′ may include means for determining a set of parameters for the plurality of channels to maximize energy efficiency. Finally, the apparatus 602/602′ may also include means for configuring the plurality of channels based on the set of parameters.

In one aspect, the means for determining the set of parameters may be configured to: fix the LNA gain; and utilize a sub-gradient method to optimize, under the LNA gain, the transmit power for each of the plurality of channels to maximize the energy efficiency. Additionally, the means for determining the set of parameters may be configured to: select the LNA gain from a set of LNA gains; utilize a sub-gradient method to optimize, under the selected LNA gain, the transmit power for each of the plurality of channels to maximize the energy efficiency; and repeat the selecting and the utilizing to find out the optimal LNA gain and the optimal transmit power for each of the plurality of channels to maximize the energy efficiency. In one configuration, the means for determining the set of parameters may be configured to repeat the selecting and the utilizing through a linear search or a bisection search.

The aforementioned means may be one or more of the aforementioned components of the apparatus 602 and/or the processing system 714 of the apparatus 602′ configured to perform the functions recited by the aforementioned means. As described supra, the processing system 714 may include the TX Processor 316, the RX Processor 370, and the controller/processor 375 when the procedures are performed by the eNB 310. As such, in one configuration, the aforementioned means may be the TX Processor 316, the RX Processor 370, and the controller/processor 375 configured to perform the functions recited by the aforementioned means. The processing system 714 may include the TX Processor 368, the RX Processor 356, and the controller/processor 359 when the procedures are performed by the UE 350. As such, in one configuration, the aforementioned means may be the TX Processor 368, the RX Processor 356, and the controller/processor 359 configured to perform the functions recited by the aforementioned means.

It is understood that the specific order or hierarchy of blocks in the processes/flowcharts disclosed is an illustration of exemplary approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

What is claimed is:

1. A method of wireless communication, comprising:
communicating using a plurality of channels, wherein the plurality of channels share a low-noise amplifier (LNA); and
determining a set of parameters for the plurality of channels to maximize energy efficiency.

2. The method of claim 1, wherein the plurality of channels work in parallel.

3. The method of claim 1, wherein the plurality of channels comprises a plurality of component carriers.

4. The method of claim 1, further comprising configuring the plurality of channels based on the set of parameters.

5. The method of claim 1, wherein the energy efficiency is measured by a number of transmitted bits per unit energy.

6. The method of claim 1, wherein the energy efficiency is a combined energy efficiency of transmit circuitry in a base station and receive circuitry in user equipment, wherein the receive circuitry includes the LNA.

7. The method of claim 1, wherein the set of parameters is constrained by a maximum transmit power per channel, a maximum analog-to-digital converter (ADC) input power, a maximum baseband signal-to-noise ratio (SNR), and a maximum LNA gain.

8. The method of claim 7, wherein the determining the set of parameters comprises:
fixing an LNA gain of the LNA; and
utilizing a sub-gradient method to optimize, under the LNA gain, a transmit power for each of the plurality of channels to maximize the energy efficiency.

9. The method of claim 7, wherein the determining the set of parameters comprises:
selecting an LNA gain of the LNA from a set of LNA gains;
utilizing a sub-gradient method to optimize, under the selected LNA gain, a transmit power for each of the plurality of channels to maximize the energy efficiency; and
repeating the selecting and the utilizing to find out an optimal LNA gain and an optimal transmit power for each of the plurality of channels to maximize the energy efficiency.

10. The method of claim 9, wherein the repeating the selecting and the utilizing is through a linear search or a bisection search.

11. The method of claim 7, wherein the determining the set of parameters comprises:
fixing an LNA gain of the LNA to the maximum LNA gain; and
utilizing a sub-gradient method to optimize, under the maximum LNA gain, a transmit power for each of the plurality of channels to maximize the energy efficiency.

12. An apparatus for wireless communication, comprising:
means for communicating using a plurality of channels, wherein the plurality of channels share a low-noise amplifier (LNA); and
means for determining a set of parameters for the plurality of channels to maximize energy efficiency.

13. An apparatus for wireless communication, comprising:
a memory; and
at least one processor coupled to the memory and configured to:
communicate using a plurality of channels, wherein the plurality of channels share a low-noise amplifier (LNA); and
determine a set of parameters for the plurality of channels to maximize energy efficiency.

14. The apparatus of claim 13, wherein the plurality of channels work in parallel.

15. The apparatus of claim 13, wherein the plurality of channels comprises a plurality of component carriers.

16. The apparatus of claim 13, wherein the at least one processor is further configured to configure the plurality of channels based on the set of parameters.

17. The apparatus of claim 13, wherein the energy efficiency is measured by a number of transmitted bits per unit energy.

18. The apparatus of claim 13, wherein the energy efficiency is a combined energy efficiency of transmit circuitry in a base station and receive circuitry in user equipment, wherein the receive circuitry includes the LNA.

19. The apparatus of claim 13, wherein the set of parameters is constrained by a maximum transmit power per channel, a maximum analog-to-digital converter (ADC) input power, a maximum baseband signal-to-noise ratio (SNR), and a maximum LNA gain.

20. The apparatus of claim 19, wherein, to determine the set of parameters, the at least one processor is configured to:
fix an LNA gain of the LNA; and
utilize a sub-gradient method to optimize, under the LNA gain, a transmit power for each of the plurality of channels to maximize the energy efficiency.

21. The apparatus of claim 19, wherein, to determine the set of parameters, the at least one processor is configured to:
select an LNA gain of the LNA from a set of LNA gains;
utilize a sub-gradient method to optimize, under the selected LNA gain, a transmit power for each of the plurality of channels to maximize the energy efficiency; and
repeat the selecting and the utilizing to find out an optimal LNA gain and an optimal transmit power for each of the plurality of channels to maximize the energy efficiency.

22. The apparatus of claim 21, wherein the at least one processor is configured to repeat the selecting and the utilizing through a linear search or a bisection search.

23. The apparatus of claim 19, wherein, to determine the set of parameters, the at least one processor is configured to:
fix an LNA gain of the LNA to the maximum LNA gain; and
utilize a sub-gradient method to optimize, under the maximum LNA gain, a transmit power for each of the plurality of channels to maximize the energy efficiency.

24. A computer-readable medium storing computer executable code, comprising code to:
communicate using a plurality of channels, wherein the plurality of channels share a low-noise amplifier (LNA); and
determine a set of parameters for the plurality of channels to maximize energy efficiency.
